(19) United States
(12) Patent Application Publication
(10) Pub. No.: US 2008/0316793 A1
(43) Pub. Date: Dec. 25, 2008

(54) INTEGRATED CIRCUIT INCLUDING CONTACT CONTACTING BOTTOM AND SIDEWALL OF ELECTRODE

(76) Inventors: Jan Boris Philipp, Peekskill, NY (US); Thomas Happ, Tarrytown, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/766,819

(22) Filed: Jun. 22, 2007

(51) Int. Cl. G11C 11/21; H01L 21/06; H01L 27/24

(52) U.S. Cl. 365/148; 257/4; 438/102; 257/E45.002; 257/E21.52

(57) ABSTRACT

An integrated circuit includes a first electrode, a second electrode, and resistivity changing material between the first electrode and the second electrode. The integrated circuit includes a contact contacting a bottom and a first sidewall portion of the first electrode.

### BACKGROUND

One type of memory is resistive memory. Resistive memory utilizes the Tesistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state and from the crystalline state to the amorphous state in response to temperature changes. The temperature changes of the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The level of current and/or voltage generally corresponds to the temperature induced within the phase change material in each memory cell.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

One type of phase change memory cell is a mushroom or heater memory cell including phase change material between a bottom electrode and a top electrode. A contact couples the bottom electrode to an access device, such as a transistor or diode. The bottom electrode should heat the phase change material during programming without heating the contact or the access device.

For these and other reasons, there is a need for the present invention.

### SUMMARY

One embodiment provides an integrated circuit. The integrated circuit includes a first electrode, a second electrode, and resistivity changing material between the first electrode and the second electrode. The integrated circuit includes a contact contacting a bottom and a first sidewall portion of the first electrode.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a system.

FIG. 2 is a diagram illustrating one embodiment of a memory device.

FIG. 3A illustrates a cross-sectional view of one embodiment of a phase change element.

FIG. 3B illustrates a cross-sectional view of another embodiment of a phase change element.

FIG. 3C illustrates a cross-sectional view of another embodiment of a phase change element.

FIG. 4 illustrates a cross-sectional view of one embodiment of a preprocessed wafer.

FIG. 5 illustrates a cross-sectional view of one embodiment of the preprocessed wafer and a first dielectric material layer.

FIG. 6 illustrates a cross-sectional view of one embodiment of the preprocessed wafer and the first dielectric material layer after etching the first dielectric material layer.

FIG. 7 illustrates a cross-sectional view of one embodiment of the preprocessed wafer, the first dielectric material layer, and a spacer material layer.

FIG. 8 illustrates a cross-sectional view of one embodiment of the preprocessed wafer, the first dielectric material layer, and spacers after etching the spacer material layer.

FIG. 9A illustrates a cross-sectional view of one embodiment of the preprocessed wafer, the first dielectric material layer, and the spacers after etching the bottom contact.

FIG. 9B illustrates a cross-sectional view of another embodiment of the preprocessed wafer, the first dielectric material layer, and the spacers after etching the bottom contact.

FIG. 10 illustrates a cross-sectional view of one embodiment of the preprocessed wafer, the first dielectric material layer, the spacers, and a first electrode material layer.

FIG. 11 illustrates a cross-sectional view of one embodiment of the preprocessed wafer, the first dielectric material layer, the spacers, and a bottom electrode after planarizing the first electrode material layer.

FIG. 12 illustrates a cross-sectional view of one embodiment of the preprocessed wafer, the first dielectric material layer, the spacers, a first electrode material layer, and a second dielectric material layer.

FIG. 13 illustrates a cross-sectional view of one embodiment of the preprocessed wafer, the first dielectric material layer, the spacers, and a bottom ring electrode after planarizing the second dielectric material layer and the first electrode material layer.

FIG. 14 illustrates a cross-sectional view of one embodiment of the preprocessed wafer, the first dielectric material layer, the spacers, the bottom electrode, a phase change material layer, and a second electrode material layer.

FIG. 15 illustrates a cross-sectional view of one embodiment of the preprocessed wafer, the first dielectric material layer, the spacers, the bottom electrode, a phase change material storage location, and a top electrode after etching the second electrode material layer and the phase change material layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

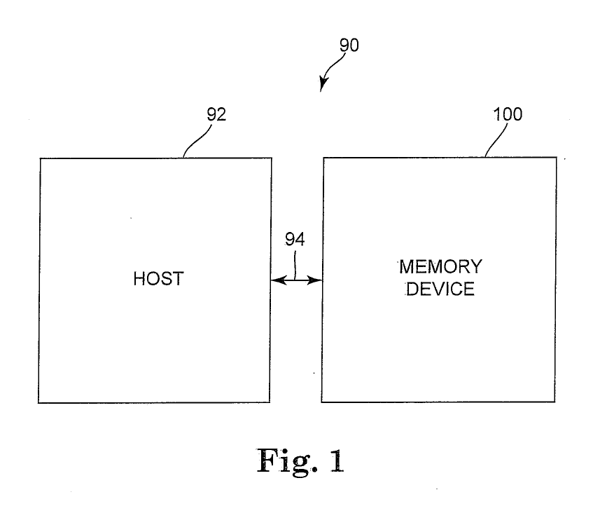

FIG. 1 is a block diagram illustrating one embodiment of a system 90. System 90 includes a host 92 and a memory device 100. Host 92 is communicatively coupled to memory device 100 through communication link 94. Host 92 includes a computer (e.g., desktop, laptop, handheld), portable electronic device (e.g., cellular phone, personal digital assistant (PDA), MP3 player, video player), or any other suitable device that uses memory. Memory device 100 provides memory for host 92. In one embodiment, memory device 100 includes a phase change memory device or other suitable resistive or resistivity changing material memory device.

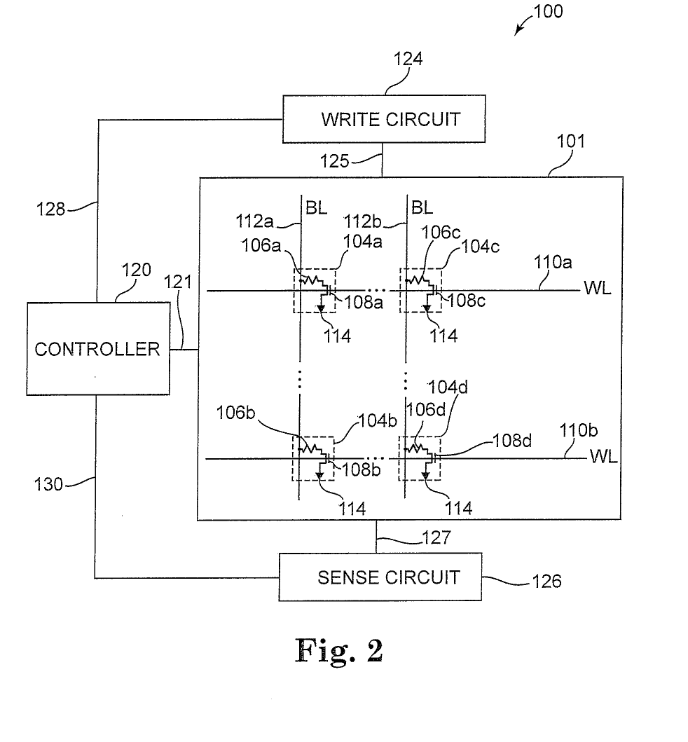

FIG. 2 is a diagram illustrating one embodiment of memory device 100. In one embodiment, memory device 100 is an integrated circuit or part of an integrated circuit. Memory device 100 includes write circuit 124, controller 120, memory array 101, and sense circuit 126. Memory array 101 includes a plurality of phase change memory cells 104a-104d (collectively referred to as phase change memory cells 104), a plurality of bit lines (BLs) 112a-112b (collectively referred to as bit lines 112), and a plurality of word lines (WLs) 110a-110b (collectively referred to as word lines 110).

Each phase change memory cell 104 includes a bottom electrode that extends or is recessed into a bottom contact. The bottom electrode is cylindrical in shape, tapered, or has another suitable shape. In one embodiment, the bottom electrode is a ring electrode, which includes a dielectric material core. The 5 bottom electrode provides an increased contact area to the bottom contact compared to bottom electrodes that do not extend into the bottom contact. The increased contact area provides improved memory cell reliability due to less heat dissipation at the interface between the bottom electrode and the bottom contact.

As used herein, the term “electrically coupled” is not meant to mean that the elements must be directly coupled together and intervening elements may be provided between the “electrically coupled” elements.

Memory array 101 is electrically coupled to write circuit 124 through signal path 125, to controller 120 through signal path 121, and to sense circuit 126 through signal path 127. Controller 120 is electrically coupled to write circuit 124 through signal path 128 and to sense circuit 126 through signal path 130. Each phase change memory cell 104 is electrically coupled to a word line 110, a bit line 112, and a common or ground 114. Phase change memory cell 104a is electrically coupled to bit line 112a, word line 110a, and common or ground 114, and phase change memory cell 104b is electrically coupled to bit line 112a, word line 110b, and common or ground 114. Phase change memory cell 104c is electrically coupled to bit line 112b, word line 110a, and common or ground 114, and phase change memory cell 104d is electrically coupled to bit line 112b, word line 110b, and common or ground 114.

Each phase change memory cell 104 includes a phase change element 106 and a transistor 108. While transistor 108 is a field-effect transistor (FET) in the illustrated embodiment, in other embodiments, transistor 108 can be another suitable device such as a bipolar transistor or a 3D transistor structure. In other embodiments, a diode-like structure may be used in place of transistor 108. Phase change memory cell 104a includes phase change element 106a and transistor 108a. One side of phase change element 106a is electrically coupled to bit line 112a, and the other side of phase change element 106a is electrically coupled to one side of the source-drain path of transistor 108a. The other side of the source-drain path of transistor 108a is electrically coupled to common or ground 114. The gate of transistor 108a is electrically coupled to word line 110a.

Phase change memory cell 104b includes phase change element 106b and transistor 108b. One side of phase change element 106b is electrically coupled to bit line 112a, and the other side of phase change element 106b is electrically coupled to one side of the source-drain path of transistor 108b. The other side of the source-drain path of transistor 108b is electrically coupled to common or ground 114. The gate of transistor 108b is electrically coupled to word line 110b.

Phase change memory cell 104c includes phase change element 106c and transistor 108c. One side of phase change element 106c is electrically coupled to bit line 112b and the other side of phase change element 106c is electrically coupled to one side of the source-drain path of transistor 108c. The other side of the source-drain path of transistor 108c is electrically coupled to common or ground 114. The gate of transistor 108c is electrically coupled to word line 110a.

Phase change memory cell 104d includes phase change element 106d and transistor 108d. One side of phase change element 106d is electrically coupled to bit line 112b and the other side of phase change element 106d is electrically coupled to one side of the source-drain path of transistor 108d. The other side of the source-drain path of transistor 108d is electrically coupled to common or ground 114. The gate of transistor 108d is electrically coupled to word line 110b.

In another embodiment, each phase change element 106 is electrically coupled to a common or ground 114 and each transistor 108 is electrically coupled to a bit line 112. For example, for phase change memory cell 104a, one side of phase change element 106a is electrically coupled to common or ground 114. The other side of phase change element 106a is electrically coupled to one side of the source-drain path of transistor 108a. The other side of the source-drain path of transistor 108a is electrically coupled to bit line 112a.

Each phase change element 106 comprises a phase change material that may be made up of a variety of materials in accordance with the present invention. Generally, chalcogenide alloys that contain one or more elements from group VI of the periodic table are useful as such materials. In one embodiment, the phase change material of phase change element 106 is made up of a chalcogenide compound material, such as GeSbTe, SbTe, GeTe or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

Each phase change element 106 may be changed from an amorphous state to a crystalline state or from a crystalline state to an amorphous state under the influence of temperature change. The amount of crystalline material coexisting with amorphous material in the phase change material of one of the phase change elements 106a-106d thereby defmes two or more states for storing data within memory device 100. In the amorphous state, a phase change material exhibits significantly higher resistivity than in the crystalline state. Therefore, the two or more states of phase change elements 106a-106d differ in their electrical resistivity. In one embodiment, the two or more states are two states and a binary system is used, wherein the two states are assigned bit values of “0” and “1”. In another embodiment, the two or more states can be three states and a ternary system can be used, wherein the three states are assigned bit values of “0”, “1”, and “2”. In another embodiment, the two or more states are four states that can be assigned multi-bit values, such as “00”, “01”, “10”, and “11”. In other embodiments, the two or more states can be any suitable number of states in the phase change material of a phase change element.

Controller 120 includes a microprocessor, microcontroller, or other suitable logic circuitry for controlling the operation of memory device 100. Controller 120 controls read and write operations of memory device 100 including the application of control and data signals to memory array 101 through write circuit 124 and sense circuit 126. In one embodiment, write circuit 124 provides voltage pulses through signal path 125 and bit lines 112 to memory cells 104 to program the memory cells. In other embodiments, write circuit 124 provides current pulses through signal path 125 and bit lines 112 to memory cells 104 to program the memory cells.

Sense circuit 126 reads each of the two or more states of memory cells 104 through bit lines 112 and signal path 127. In one embodiment, to read the resistance of one of the memory cells 104, sense circuit 126 provides current that flows through one of the memory cells 104. Sense circuit 126 then reads the voltage across that one of the memory cells 104. In one embodiment, sense circuit 126 provides voltage across one of the memory cells 104 and reads the current that flows through that one of the memory cells 104. In one embodiment, write circuit 124 provides voltage across one of the memory cells 104 and sense circuit 126 reads the current that flows through that one of the memory cells 104. In one embodiment, write circuit 124 provides current that flows through one of the memory cells 104 and sense circuit 126 reads the voltage across that one of the memory cells 104.

During a set operation of phase change memory cell 104a, one or more set current or voltage pulses are selectively enabled by write circuit 124 and sent through bit line 112a to phase change element 106a thereby heating phase change element 106a above its crystallization temperature (but usually below its melting temperature) with word line 110a selected to activate transistor 108a. In this way, phase change element 106a reaches its crystalline state or a partially crystalline and partially amorphous state during this set operation.

During a reset operation of phase change memory cell 104a, a reset current or voltage pulse is selectively enabled by write circuit 124 and sent through bit line 112a to phase change element 106a. The reset current or voltage quickly heats phase change element 106a above its melting temperature. After the current or voltage pulse is turned off, phase change element 106a quickly quench cools into the amorphous state or a partially amorphous and partially crystalline state. Phase change memory cells 104b-104d and other phase change memory cells 104 in memory array 100 are set and reset similarly to phase change memory cell 104a using a similar current or voltage pulse.

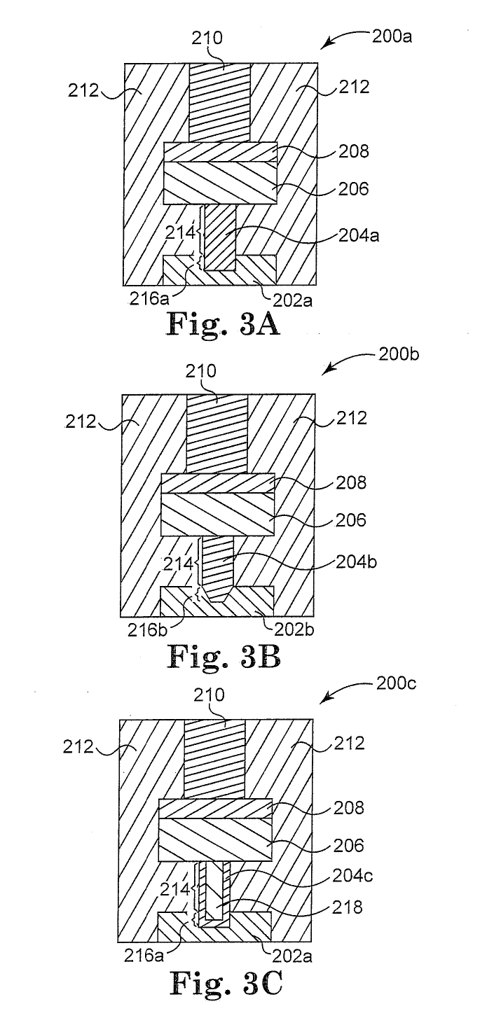

FIG. 3A illustrates a cross-sectional view of one embodiment of a phase change element 200a. In one embodiment, each phase change element 106 is similar to phase change element 200a. Phase change element 200a includes a bottom contact 202a, a bottom electrode 204a, a phase change material storage location 206, a top electrode 208, a top contact 210, and dielectric material 212. Bottom electrode 204a includes a first portion 216a and a second portion 214.

Bottom contact 202a includes TiN, TaN, W, Al, Ti, Ta, TiSiN, TaSiN, TiAlN, TaAlN, Cu, WN, C, or other suitable contact material. Bottom contact 202a contacts the bottom and sidewalls of first portion 216a of bottom electrode 204a. In one embodiment, the height of first portion 216a is greater than 10% of the critical dimension or diameter of bottom electrode 204a. In another embodiment, the height of first portion 216a is greater than 50% of the critical dimension or diameter of bottom electrode 204a. In one embodiment, bottom electrode 204a has a sublithographic cross-sectional width. Bottom electrode 204a includes TiN, TaN, W, Al, Ti, Ta, TiSiN, TaSiN, TiAlN, TaAlN, WN, C, Ru, or other suitable electrode material.

The top of second portion 214 of bottom electrode 204a contacts the bottom of phase change material storage location 206. Phase change material storage location 206 has a greater cross-sectional width than bottom electrode 204a. Phase change material storage location 206 provides a storage location for storing one or more bits of data. The active or phase change region in phase change material storage location 206 is at the interface between phase change material storage location 206 and bottom electrode 204a. In one embodiment, phase change material storage location 206 includes two or more layers of phase change material or a graded composition of two or more phase change materials.

The top phase change material storage location 206 contacts the bottom of top electrode 208. In one embodiment, top electrode 208 has the same cross-sectional width as phase change material storage location 206. Top electrode 208 includes TiN, TaN, W, Al, Ti, Ta, TiSiN, TaSiN, TIAlN, WN, C, or other suitable electrode material. The top of top electrode 208 contacts the bottom of top contact 210. Top contact 210 includes TiN, TaN, W, Al, Ti, Ta, TiSiN, TaSiN, TiAlN, WN, C, or other suitable contact material. Top contact 210, top electrode 208, phase change material storage location 206, second portion 214 of bottom electrode 204a, and bottom contact 202a are laterally surrounded by dielectric material 212. Dielectric material 212 includes SiO₂, SiOₓ, SiN, fluorinated silica glass (FSG), boro-phosphorous silicate glass (BPSG), boro-silicate glass (BSG), or other suitable dielectric material.

The current path through memory element 200a is from top contact 210 through top electrode 208, phase change material storage location 206, and bottom electrode 204a to bottom contact 202a. In another embodiment, the current path is reversed. During operation, current or voltage pulses are applied between top contact 210 and bottom contact 202a to program phase change element 200a. During a set operation of phase change element 200a, a set current or voltage pulse is selectively enabled by write circuit 124 and sent through a bit line to top contact 210. From top contact 210, the set current or voltage pulse passes through top electrode 208 and phase change material storage location 206 thereby heating the phase change material above its crystallization temperature (but usually below its melting temperature). In this way, the phase change material reaches a crystalline state or a partially crystalline and partially amorphous state during the set operation.

During a reset operation of phase change element 200a, a reset current or voltage pulse is selectively enabled by write circuit 124 and sent through a bit line to top contact 210. From top contact 210, the reset current or voltage pulse passes through top electrode 208 and phase change material storage location 206. The reset current or voltage quickly heats the phase change material above its melting temperature. After the current or voltage pulse is turned off, the phase change material quickly quench cools into an amorphous state or a partially amorphous and partially crystalline state.

FIG. 3B illustrates a cross-sectional view of another embodiment of a phase change element 200b. Phase change element 200b is similar to phase change element 200a previously described and illustrated with reference to FIG. 3A, except that for phase change element 200b bottom contact 202a and bottom electrode 204a are replaced with bottom contact 202b and bottom electrode 204b. In this embodiment, bottom electrode 204b includes a first tapered portion 216b and second portion 214. Bottom contact 202b contacts the bottom and tapered sidewalls of first portion 216b of bottom electrode 204b. In one embodiment, each phase change element 106 is similar to phase change. element 200b. Phase change element 200b operates similarly to phase change element 200a previously described and illustrated with reference to FIG. 3A.

FIG. 3C illustrates a cross-sectional view of another embodiment of a phase change element 200c. Phase change element 200c is similar to phase change element 200a previously described and illustrated with reference to FIG. 3A, except that for phase change element 200c bottom electrode 204a is replaced with bottom electrode 204c . In this embodiment, bottom electrode 204c is a ring electrode including a dielectric or semiconducting material core 218. In one embodiment, each phase change element 106 is similar to phase change element 200c. Phase change element 200c operates similarly to phase change element 200a previously described and illustrated with reference to FIG. 3A.

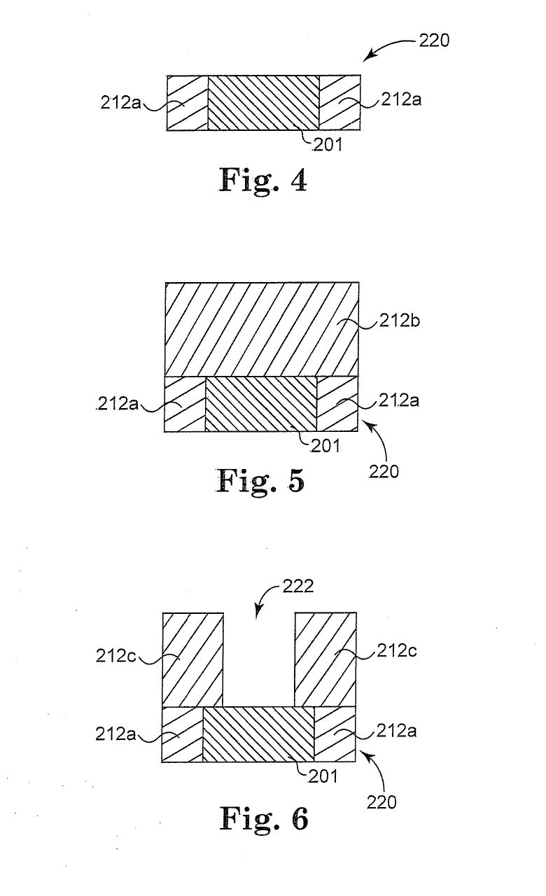

The following FIGS. 4-15 illustrate embodiments for fabricating a phase change element, such as phase change element 200a-200c previously described and illustrated with reference to FIGS. 3A-3C.

FIG. 4 illustrates a cross-sectional view of one embodiment of a preprocessed wafer 220. Preprocessed wafer 220 includes a bottom contact 201, dielectric material 212a, and lower wafer layers (not shown). In one embodiment, the lower wafer layers include access devices, such as transistors or diodes, where each transistor or diode is coupled to a bottom contact 201. Bottom contact 201 includes TiN, TaN, W, Al, Ti, Ta, TiSiN, TaSiN, TIAlN, TaAlN, Cu, WN, C, or other suitable contact material. Bottom contact 201 is laterally surrounded by dielectric material 212a. Dielectric material 212a includes SiO₂, SiOₓ, SiN, FSG, BPSG, BSG, or other suitable dielectric material.

FIG. 5 illustrates a cross-sectional view of one embodiment of preprocessed wafer 220 and a first dielectric material layer 212b. A dielectric material, such as SiO₂, SiOₓ, SiN, FSG, BPSG, BSG, or other suitable dielectric material is deposited over preprocessed wafer 220 to provide first dielectric material layer 212b. First dielectric material layer 212b is deposited using chemical vapor deposition (CVD), high density plasma-chemical vapor deposition (HDP-CVD), atomic layer deposition (ALD), metal organic chemical vapor deposition (MOCVD), physical vapor deposition (PVD), jet vapor deposition (JVD), or other suitable deposition technique.

FIG. 6 illustrates a cross-sectional view of one embodiment of preprocessed wafer 220 and first dielectric material layer 212c after etching first dielectric material layer 212b. First dielectric material layer 212b is etched using reactive ion etching (RIE) or another suitable etching technique to provide an opening 222 exposing a portion of bottom contact 201. In one embodiment, opening 222 is substantially centered over bottom contact 201. In one embodiment, opening 222 is cylindrical in shape. In other embodiments, opening 222 has other suitable shapes.

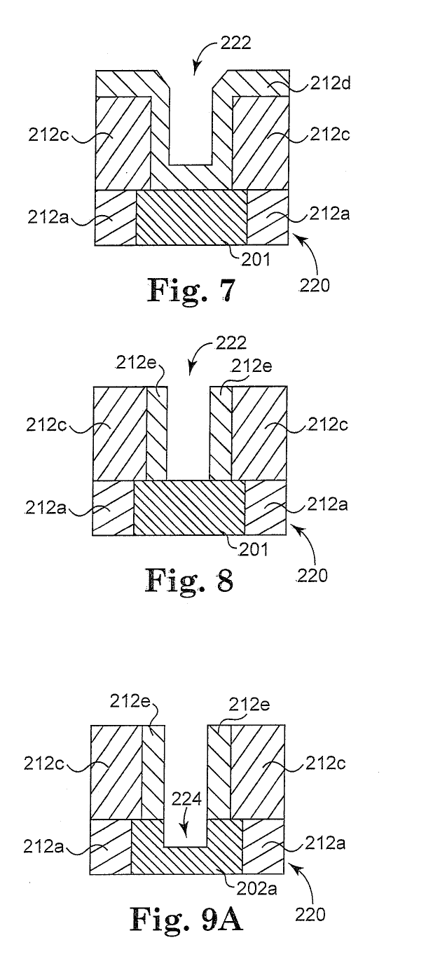

FIG. 7 illustrates a cross-sectional view of one embodiment of preprocessed wafer 220, first dielectric material layer 212c, and a spacer material layer 212d. A spacer material, such as SiO₂, SiOₓ, SiN, or other suitable spacer material is conformally deposited over exposed portions of first dielectric material layer 212c and bottom contact 201 to provide spacer material layer 212d. Spacer material layer 212d is deposited using CVD, HDP-CVD, ALD, MOCVD, PVD, JVD, or other suitable deposition technique.

FIG. 8 illustrates a cross-sectional view of one embodiment of preprocessed wafer 220, first dielectric material layer 212c, and spacers 212e after etching spacer material layer 212d. Spacer material layer 212d is spacer etched using RIE or another suitable etching technique to expose a portion of bottom contact 201 and first dielectric material layer 212c to provide spacers 212e on the sidewalls of opening 222. In one embodiment, spacers 212e reduce the cross-sectional width of the exposed portion of bottom contact 201 to a sublithographic width.

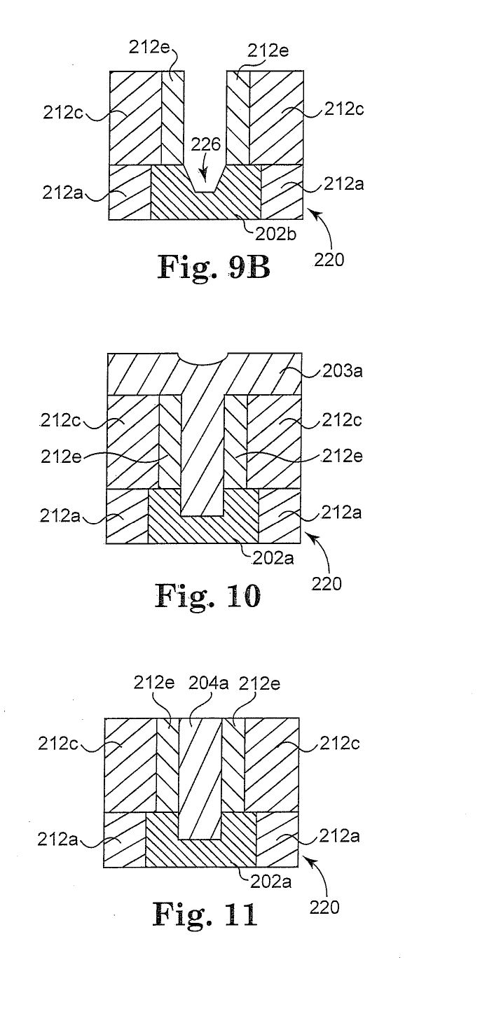

FIG. 9A illustrates a cross-sectional view of one embodiment of preprocessed wafer 220, first dielectric material layer 212c, and spacers 212e after etching bottom contact 201. Bottom contact 201 is etched using RIE or another suitable etching technique self-aligned to spacers 212e to form an opening 224 to provide bottom contact 202a. Bottom contact 202a is part of phase change element 200a previously described and illustrated with reference to FIG. 3A.

FIG. 9B illustrates a cross-sectional view of another embodiment of preprocessed wafer 220, first dielectric material layer 212c, and spacers 212e after etching bottom contact 201. Bottom contact 201 is taper etched using RIE or another suitable etching technique self-aligned to spacers 212e to form a tapered opening 226 to provide bottom contact 202b. Bottom contact 202b is part of phase change element 200b previously described and illustrated with reference to FIG. 3B. In other embodiments, bottom contact 201 is etched to provide another suitably shaped opening, such as a ball or bottle shaped opening formed using an isotropic etch. While bottom contact 202a is used in the following FIGS. 10-15, in other embodiments bottom contact 202a can be replaced with bottom contact 202b.

FIG. 10 illustrates a cross-sectional view of one embodiment of preprocessed wafer 220, first dielectric material layer 212c, spacers 212e, and a first electrode material layer 203 a. An electrode material, such as TiN, TaN, W, Al, Ti, Ta, TiSiN, TaSiN, TiAIN, TaAlN, Cu, WN, C, or other suitable electrode material is deposited over exposed portions of first dielectric material layer 212c, spacers 212e, and bottom contact 202a to provide first electrode material layer 203a. First electrode material layer 203a is deposited using CVD, HDP-CVD, ALD, MOCVD, PVD, JVD, or other suitable deposition technique.

FIG. 11 illustrates a cross-sectional view of one embodiment of preprocessed wafer 220, first dielectric material layer 212c, spacers 212e, and bottom electrode 204a after planarizing first electrode material layer 203a. First electrode material layer 203a is planarized to expose first dielectric material layer 212c and spacers 212e to provide bottom electrode 204a. First electrode material layer 203a is planarized using chemical mechanical planarization (CMP) or another suitable planarization technique.

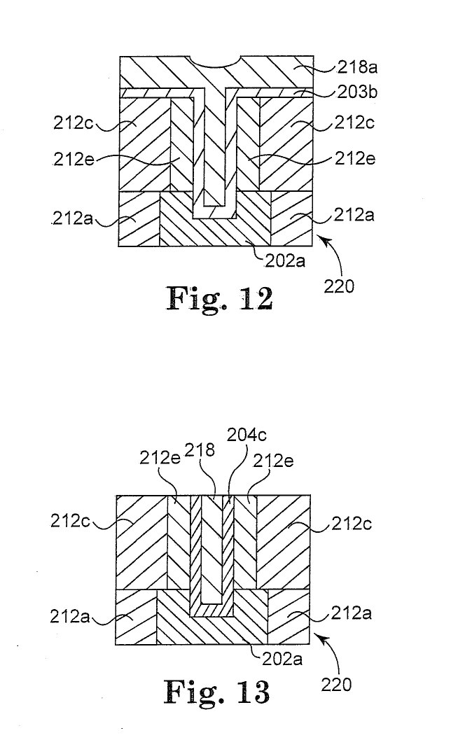

The following FIGS. 12 and 13 illustrate one embodiment for fabricating a bottom ring electrode as previously described and illustrated with reference to FIG. 3C.

FIG. 12 illustrates a cross-sectional view of one embodiment of preprocessed wafer 220, first dielectric material layer 212c, spacers 212e, a first electrode material layer 203b, and a second dielectric material layer 218a. An electrode material, such as TiN, TaN, W, Al, Ti, Ta, TiSiN, TaSiN, TIAlN, TaAlN, Cu, WN, C, or other suitable electrode material is conformally deposited over exposed portions of first dielectric material layer 212c, spacers 212e, and bottom contact 202a to provide first electrode material layer 203b. First electrode material layer 203b is deposited using CVD, HDP-CVD, ALD, MOCVD, PVD, JVD, or other suitable deposition technique.

A dielectric material, such as SiO₂, SiOₓ, SiN, FSG, BPSG, BSG, or other suitable dielectric material is deposited over first electrode material layer 203b to provide second dielectric material layer 218a. Second dielectric material layer 218a is deposited using CVD, HDP-CVD, ALD, MOCVD, PVD, JVD, or other suitable deposition technique.

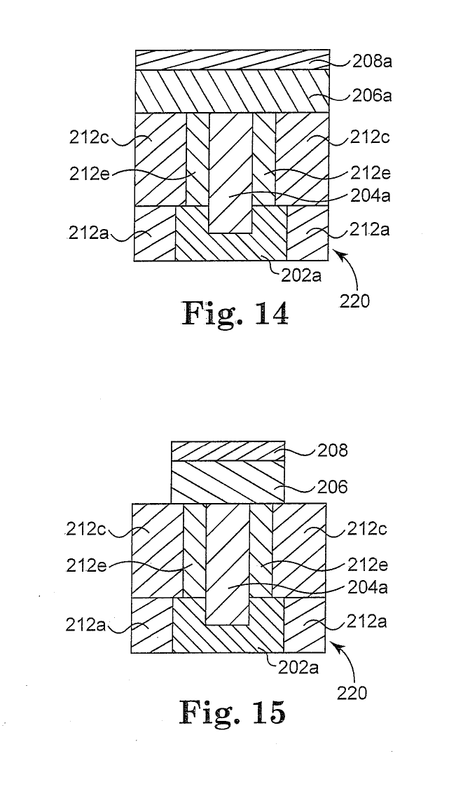

FIG. 13 illustrates a cross-sectional view of one embodiment of preprocessed wafer 220, first dielectric material layer 212c, spacers 212e, and a bottom ring electrode 204c after planarizing second dielectric material layer 218a and first electrode material layer 203b. Second dielectric material layer 218a and first electrode material layer 203b are planarized to expose first dielectric material layer 212c and spacers 212e to provide bottom ring contact 204c including a dielectric material core 218. Second dielectric material layer 218a and first electrode material layer 203b are planarized using CMP or another suitable planarization technique. While bottom electrode 204a is used in the following FIGS. 14 and 15, in other embodiments bottom electrode 204a can be replaced with bottom ring electrode 204c.

FIG. 14 illustrates a cross-sectional view of one embodiment of preprocessed wafer 220, first dielectric material layer 212c, spacers 212e, bottom electrode 204a, a phase change material layer 206a, and a second electrode material layer 208a. A phase change material, such as a chalcogenide compound material or other suitable phase change material is deposited over exposed portions of first dielectric material layer 212c, spacers 212e, and bottom electrode 204a to provide phase change material layer 206a. Phase change material layer 206a is deposited using CVD, HDP-CVD, ALD, MOCVD, PVD, JVD, or other suitable deposition technique.

An electrode material, such as TiN, TaN, W, Al, Ti, Ta, TiSiN, TaSiN, TiAlN, TaAlN, Cu, WN, C, or other suitable electrode material is deposited over phase change material layer 206a to provide second electrode material layer 208a. Second electrode material layer 208a is deposited using CVD, HDP-CVD, ALD, MOCVD, PVD, JVD, or other suitable deposition technique.

FIG. 15 illustrates a cross-sectional view of one embodiment of preprocessed wafer 220, first dielectric material layer 212c, spacers 212e, bottom electrode 204a, a phase change material storage location 206, and a top electrode 208 after etching second electrode material layer 208a and phase change material layer 206a. Second electrode material layer 208a and phase change material layer 206a are etched to expose portions of first dielectric material layer 212c and to provide phase change material storage location 206 and top electrode 208. In one embodiment, top electrode 208 and phase change material storage location 206 are substantially centered over bottom electrode 204a.

A dielectric material, such as SiO₂, SiOₓ, SiN, FSG, BPSG, BSG, or other suitable dielectric material is then deposited over exposed portions of top electrode 208, phase change material storage location 206, and first dielectric material layer 212c to provide a dielectric material layer. The dielectric material layer is deposited using CVD, HDP-CVD, ALD, MOCVD, PVD, JVD, or other suitable deposition technique. The dielectric material layer is then planarized using CMP or another suitable planarization technique. Top contact 210 is then formed over top electrode 208 using additional deposition and etching processes to provide phase change element 200a-200c as previously described and illustrated with reference to FIGS. 3A-3C.

Embodiments provide a heater phase change memory cell including a bottom electrode that extends or is recessed into a bottom contact. In one embodiment, the portion of the bottom electrode that extends or is recessed into the bottom contact is tapered. In one embodiment, the bottom electrode includes a ring electrode. The interface area between the bottom electrode and the bottom contact is increased over typical heater memory cells thereby improving the reliability of the memory cells.

While the specific embodiments described herein substantially focused on using phase change memory elements, the present invention can be applied to any suitable type of resistive or resistivity changing memory elements.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a first electrode;
a second electrode;
resistivity changing material between the first electrode and the second electrode; and
a contact contacting a bottom and a first sidewall portion of the first electrode.

2. The integrated circuit of claim 1, wherein the first sidewall portion of the first electrode is tapered.

3. The integrated circuit of claim 1, wherein the first electrode comprises a ring electrode.

4. The integrated circuit of claim 1, wherein the first electrode has a sublithographic cross-section.

5. The integrated circuit of claim 1, further comprising:
a spacer defining a second sidewall portion of the first electrode.

6. The integrated circuit of claim 1, wherein the resistivity changing material comprises phase change material.

7. A system comprising:
a host; and
a memory device communicatively coupled to the host, the memory device comprising:
a first electrode;
a second electrode;
phase change material between the first electrode and the second electrode; and
a contact contacting a bottom and a first sidewall portion of the first electrode.

8. The system of claim 7, wherein the first sidewall portion of the first electrode is tapered.

9. The system of claim 7, wherein the first electrode comprises a ring electrode.

10. The system of claim 7, wherein the first electrode has a sublithographic cross-section.

11. The system of claim 7, wherein the memory device further comprises:
a spacer defining a second sidewall portion of the first electrode.

12. The system of claim 7, wherein the memory device further comprises:
a write circuit configured to program the phase change material;
a sense circuit configured to read a state of the phase change material; and
a controller configured to control the write circuit and the sense circuit.

13. A memory comprising:
a first electrode;
a second electrode;
means for storing data between the first electrode and the second electrode; and
a contact,
wherein the first electrode is recessed into the contact.

14. The memory of claim 13, further comprising:
means for accessing the means for storing data.

15. The memory of claim 13, wherein the recess is greater than 10% of a diameter of the first electrode.

16. The memory of claim 13, wherein the recess is greater than 50% of a diameter of the first electrode.

17. The memory of claim 13, wherein the first electrode comprises a ring electrode.

18. The memory of claim 13, wherein a cross-sectional width of the means for storing data is greater than a cross-sectional width of the first electrode.

19. A method for fabricating an integrated circuit having a memory cell, the method comprising:
providing a preprocessed wafer including a contact and dielectric material over the contact, the dielectric material including a first opening exposing a portion of the contact;
etching the exposed portion of the contact to provide a second opening within the contact;
depositing electrode material within the second opening and the first opening to provide a first electrode;
fabricating a storage location coupled to the first electrode; and
fabricating a second electrode coupled to the storage location.

20. The method of claim 19, wherein etching the exposed portion of the contact to provide the second opening comprises etching the exposed portion of the contact to provide a tapered second opening within the contact.

21. The method of claim 19, wherein depositing electrode material within the second opening and the first opening to provide the first electrode comprises conformally depositing electrode material within the second opening and the first opening to provide a ring electrode.

22. The method of claim 19, wherein fabricating the storage location comprises fabricating a phase change material storage location.

23. A method for fabricating a memory cell, the method comprising:
providing a preprocessed wafer including a first contact;
depositing a first dielectric material layer over the preprocessed wafer;
etching a first opening in the first dielectric material layer to expose the first contact;
conformally depositing a spacer material layer over exposed portions of the etched first dielectric material layer and the preprocessed wafer;
etching the spacer material layer to expose a portion of the first contact and to provide spacers on sidewalls of the first opening;
etching the exposed portion of the first contact self-aligned to the spacers to provide a second opening within the first contact;
depositing electrode material over exposed portions of the etched first dielectric material layer, the spacers, and the first contact;
planarizing the electrode material to expose the etched first dielectric material layer and the spacers to provide a first electrode;
fabricating a phase change material storage location coupled to the first electrode; and
fabricating a second electrode coupled to the storage location.

24. The method of claim 23, wherein etching the exposed portion of the first contact to provide the second opening comprises etching the exposed portion of the first contact to provide a tapered second opening within the first contact.

25. The method of claim 23, wherein depositing electrode material comprises conformally depositing electrode material, the method further comprising:
depositing a second dielectric material layer over the electrode material,
wherein planarizing comprises planarizing the second dielectric material layer and the electrode material to expose the etched first dielectric material layer and the spacers to provide a first ring electrode.

26. The method of claim 23, further comprising:
fabricating a second contact coupled to the second electrode.
